(19) United States
(12) Patent Application Publication
(10) Pub. No.: US 2009/0014051 A1
(43) Pub. Date: Jan. 15, 2009

(54) System and Method Utilizing Re-Deployable Insulated Self-Ballasted Photovoltaic Assemblies

(76) Inventor: Michael Gumm, Largo, FL (US)

Correspondence Address: PATWRITE LLC, 408 W. MAIN ST., MARSHALLTOWN, IA, 50158-5759, US

(21) Appl. No.: 12/122,070

(22) Filed: May 16, 2008

Related U.S. Application Data
(60) Provisional application No. 60/959,530, filed on Jul. 14, 2007.
(60) Provisional application No. 61/003,202, filed on Nov. 15, 2007.

(51) Int. Cl. H01L 31/042; E04D 13/18

(52) U.S. Cl. 136/244; 52/173.3

(57) ABSTRACT

A system and method of utilizing redeployable insulted self-ballasted photovoltaic modules comprises an insulative panel removeably attached to a substrate such as a roof, wall or other structure. A photovoltaic module is attached to the insulative panel. The insulative panel has tongue and groove attachment ends to fit a plurality of panels together. In one embodiment, an elastomeric coating is applied to the surface of the insulative panel to attach the photovoltaic module and to weatherproof the surface. In another embodiment, adhesives are used to attach the modules. A structural panel may be used to enhance performance. In one embodiment, a corrugated channel panel is used to circulate a fluid like water through the channels to cool the photovoltaic panels and or heat water. Various raceways and associated wiring is installed to complete the system. An elastomeric coating may be used to enhance the weatherability of the system.

### RELATED APPLICATIONS

This application claims priority to Provisional Application Ser. Nos. 60/959,530, filed on Jul. 14, 2007, and 61/003,202, filed on Nov. 15, 2007, the complete disclosures of each of which are hereby incorporated by reference.

### BACKGROUND OF THE INVENTION

There are a number of methods for installing photovoltaic devices on roofs, walls and other surfaces. Installation methods include frame and rack arrays or post mounted systems using rigid panels of crystalline-based silicon, Copper Indium Selenide (CIS), Copper Indium Gallium Selenide (CIGS), or amorphous silicon based photovoltaic modules. These rigid panels systems can be ground-based, wall mounted or roof mounted array systems. Other photovoltaic installation systems include laminating flexible thin film modules to single-ply membrane roofs or adhering photovoltaic modules to metal roof panels.

A recently invented method is to combine any elastomeric coatings with any flexible or semi-flexible photovoltaic modules applied to any surface to create a monolithic weatherproof surface capable of generating renewable energy from the sun.

Another installation method is a lightweight inverted photovoltaic roof system. This self-ballasting roof system consists of an extruded polystyrene insulation panel with a thin laminate of latex modified concrete with a rigid glass on glass photovoltaic module adhered to the insulation panel's concrete surface with a series of spacers. The spacers create a space between the panel top surface and the lower surface of the raised photovoltaic module to provide airflow between the insulation panel and photovoltaic module to promote photovoltaic module cooling as disclosed in U.S. Pat. No. 4,886,554 issued Dec. 12, 1989 to Woodring et al.

Since the Woodring patent, a number of new patents have continued to modify the basic construction of lightweight self-ballasting photovoltaic roof systems including U.S. Pat. No. 5,316,592 dated May 31, 1994 to Dinwoodie and U.S. Pat. No. 6,809,253 dated Oct. 26, 2004 also to Dinwoodie. The patented lightweight self-ballasting photovoltaic roof system is marketed under the name of PowerGuard® by the Powerlight Corporation.

The insulation panel typically used in the lightweight self-ballasting photovoltaic roof system is an extruded polystyrene insulation board of varying thickness with a tongue and groove edge profile and a ⅜″ to 15/16″ inch concrete topping layer that was first patented by Dow and is currently manufactured and marketed by the T-Clear Corporation. The insulation panel was sold under the LIGHTGUARD and HEAVYGUARD brand names by DOW and now by the T-Clear Corporation.

The Lightguard and Heavyguard insulation boards continue to be used in a number of regular commercial roof and waterproofing applications commonly referred as to IRMA® (Inverted Roof Membrane Assembly) or PMR (Protective Membrane Roof) roof systems. These are inverted roofing or waterproofing systems. The waterproofing membranes in these systems are protected from the elements by the insulation panel overlay. Adding ballast (paver/large rock ballast) or a self-ballasting insulation panel such as the T-Clear panels holds down the insulation panels. To interlock the panels they are connected and joined by a tongue and groove edge, metal bands, metal flashings, various types of fasteners and even adhesives.

Extruded Polystyrene is the only thermal insulation that is proven to perform in a PMR configuration as water absorption, freeze-thaw, rot, warping, or mildew attack would degrade all other common insulation materials. At one time Styrofoam® from Dow Chemical was the only extruded polystyrene available, and the PMR configuration was covered by Dow patents. The patents on both extruded polystyrene and IRMA roof systems are now expired. Extruded polystyrene is now manufactured by both DOW and Owens-Corning.

A number of conventional roof material manufacturers market inverted PRM roofing and waterproofing assemblies with single-ply, built-up roofing, modified bitumen and coated membrane systems under various brand names. Other roofing and waterproofing inverted assemblies including the PowerGuard system use a laminated composite panel constructed with an extruded polystyrene insulation without the factory installed concrete toping. In some cases a top surface board, made from hard and waterproof materials is laminated to the insulation board with an adhesive.

In another PowerGuard® embodiment, the extruded polystyrene board is first machined to create the various surface profiles outlined in the listed patents and coated with a protective paint to prevent UV degradation in conjunction with the shading from the photovoltaic module above the spacer attached to the insulation board top surface. Both types of polystyrene boards are machined in the factory to provide wiring channel under the insulation board and the rigid glass on glass Photovoltaic modules with spacers is assembled into a single component for shipping and roof system is assembled on the roof.

When the PowerGuard® System is installed on the roof, the system uses both standard roof details developed by the T-Clear Corporation for a warranted roof system and wind resistances and certain proprietary installation methods for securing the photovoltaic module and insulation panels onto the roof along with wiring and interconnecting the photovoltaic modules.

### SUMMARY OF THE INVENTION

A system and method of utilizing redeployable insulted self-ballasted photovoltaic modules comprises an insulative panel removeably attached to a substrate such as a roof, wall or other structure. A photovoltaic module is attached to the insulative panel. The insulative panel has tongue and groove attachment ends to fit a plurality of panels together. In one embodiment, an elastomeric coating is applied to the surface of the insulative panel to attach the photovoltaic module and to weatherproof the surface. In another embodiment, adhesives are used to attach the modules. A structural panel may be used to enhance performance. In one embodiment, a corrugated channel panel is used to circulate a fluid like water through the channels to cool the photovoltaic panels and or heat water. Various raceways and associated wiring is installed to complete the system. An elastomeric coating may be used to enhance the weatherability of the system.

Other features and advantages of the instant invention will become apparent from the following description of the invention which refers to the accompanying drawings.

### BRIEF DESCRIPTION OF THE DRAWINGS

FIG. 1 is a top view of a photovoltaic system according to an embodiment of the present invention.

FIG. 2 is a side view of a photovoltaic system according to an embodiment of the present invention.

FIG. 3 is a side view of a photovoltaic system according to an embodiment of the present invention.

FIG. 4 is a side view of a photovoltaic system according to an embodiment of the present invention.

FIG. 5 is a side view of a photovoltaic system according to an embodiment of the present invention.

FIG. 6 is a side view of a photovoltaic system according to an embodiment of the present invention.

FIG. 7 is a side view of a photovoltaic system according to an embodiment of the present invention.

FIG. 8 is a top view of a photovoltaic system according to an embodiment of the present invention.

FIG. 9 is a detail view of the section shown in FIG. 8.

FIG. 10 is a side view of a photovoltaic system according to an embodiment of the present invention.

FIG. 11 is a side view of a photovoltaic system according to an embodiment of the present invention.

FIG. 12 is a top view of a photovoltaic system according to an embodiment of the present invention.

FIG. 13 is a side view of a photovoltaic system according to an embodiment of the present invention.

FIG. 14 is a side view of a photovoltaic system according to an embodiment of the present invention.

FIG. 15 is a top view of a structural panel according to an embodiment of the present invention.

FIG. 16 is a top view of a plurality of photovoltaic modules according to an embodiment of the present invention.

FIG. 17 is a side view of a photovoltaic system according to an embodiment of the present invention.

### DETAILED DESCRIPTION OF THE INVENTION

In the following detailed description of the invention, reference is made to the drawings in which reference numerals refer to like elements, and which are intended to show by way of illustration specific embodiments in which the invention may be practiced. It is understood that other embodiments may be utilized and that structural changes may be made without departing from the scope and spirit of the invention.

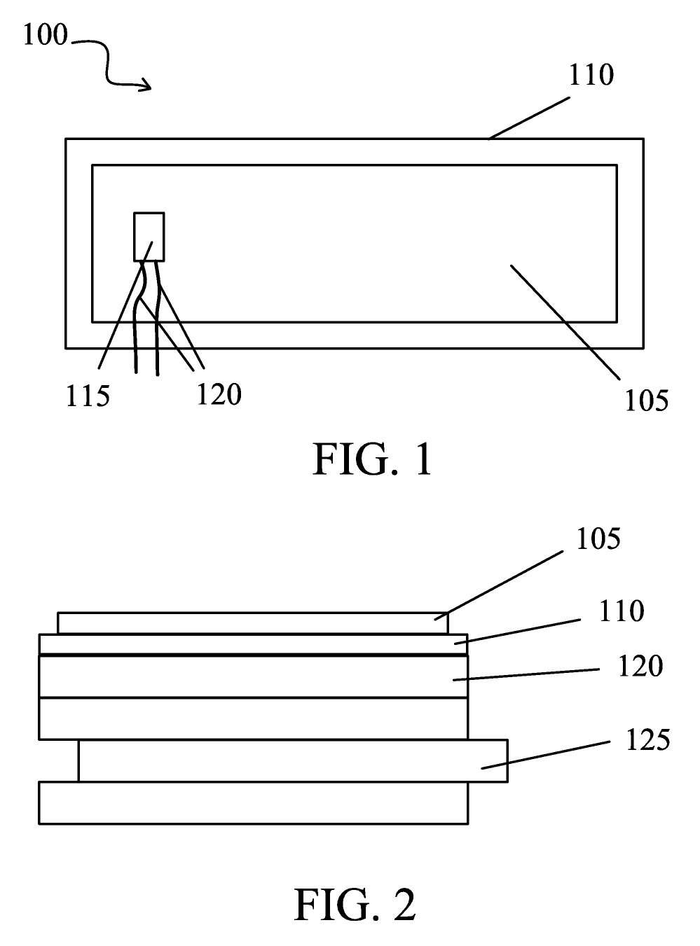

Referring to FIGS. 1 and 2, a photovoltaic system 100 comprises at least one photovoltaic module 105 adhered to at least one elastomeric layer 110. Elastomeric layer 110 is used to provide a weatherproof surface protecting a substrate like a roof, wall or other structure. In the embodiment shown, a construction sheet 120 is laminated with an insulative panel 125 to form a strong base to support photovoltaic module 105. Construction sheet 120 is a reinforced latex modified cementitious board. Other sheets may be used such as silicone treated gypsum board or other hard surface boards. Insulative panel 125 has a tongue and groove section facilitating connecting a plurality of modules. A module bus box 115 connects photovoltaic module 105 with external wiring 120 to connect to an inverter (not shown) and other balance of system components as is known in the art.

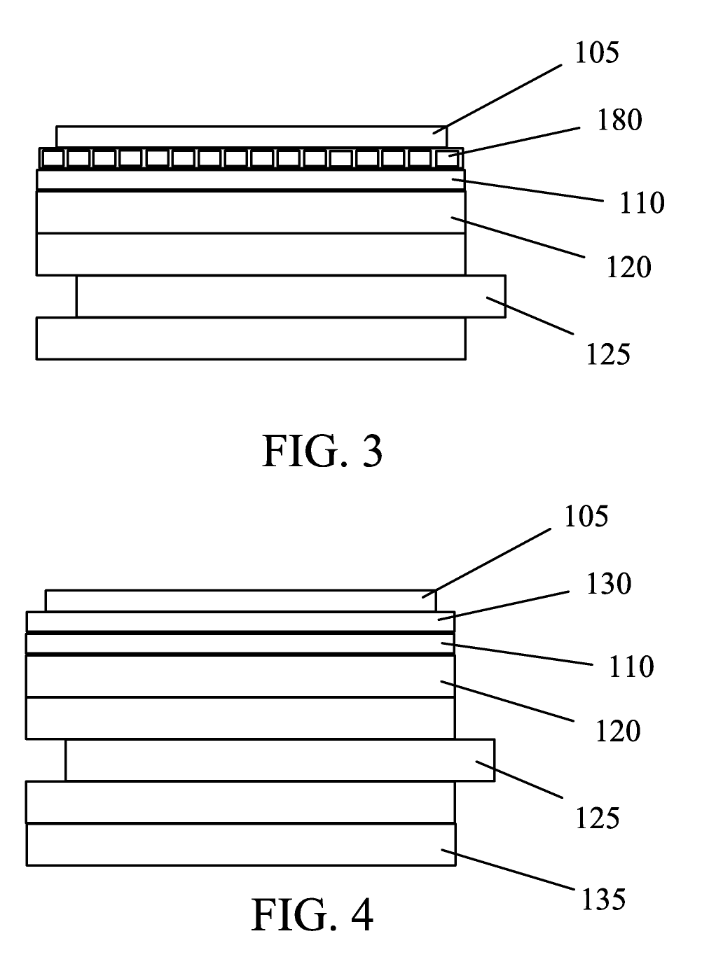

FIGS. 3 and 15 illustrate a structural panel 180 inserted between photovoltaic panel 105 and elastomeric coating 110. Structural panel 180 is a corrugated channel panel with a plurality of open channels formed therein. In the embodiment shown in FIG. 3, air is free to flow through the open channels to aid in thermal regulation of photovoltaic module 105. Corrugated channel panel 180 may be made of plastic or an aluminum-polymer-aluminum composite or other suitable material.

In the embodiment shown in FIG. 15, a fluid, most commonly water, is circulated through the channels by sealing a liquid flow cap 185 on each open end of structural panel 180. Liquid flow cap 185 may be sealed using a waterproof sealant or glue as is known in the art. An intake nipple 190 and an outlet nipple 195 is connected to a pump (not shown) to circulate the liquid to both thermally regulate the photovoltaic module 105 as well as heating water for addition energy recovery.

Also, although structural panel 180 is shown placed on elastomeric coating 110, in other embodiments, structural panel 180 is placed directly on insulative panel 125 or on construction sheet 120 using an adhesive, hook and loop fasteners, mechanical fasteners such as screws or bolts or a combination thereof.

Referring now to FIG. 4, a finish elastomeric coating 130 is applied over elastomeric coating 110. Additionally, a second construction sheet 135 is laminated on the bottom of insulative panel 125 further enhancing the structural properties of the panel.

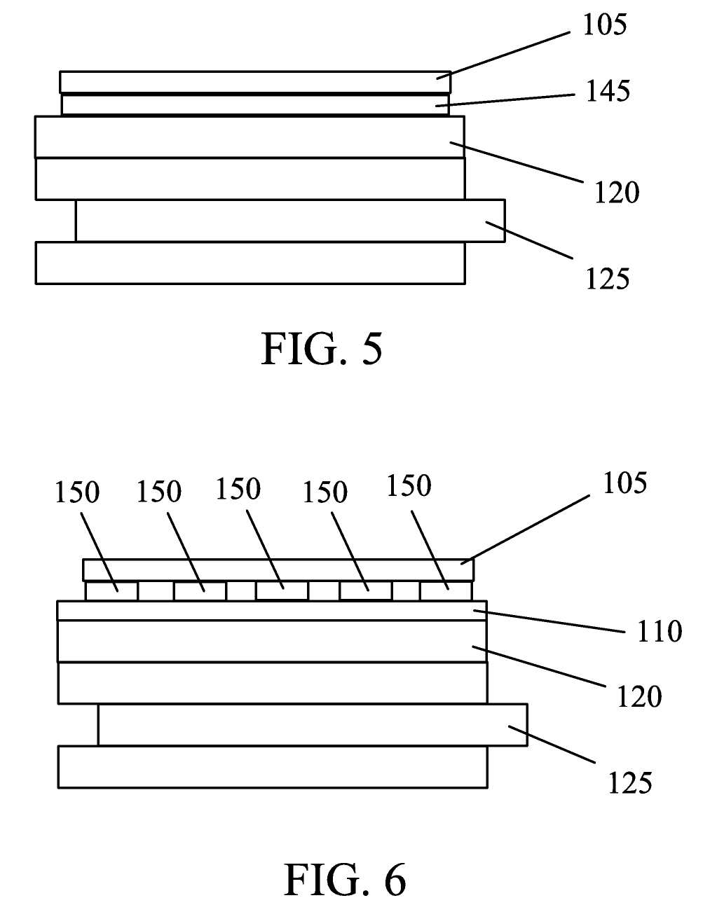

Referring to FIG. 5, a pressure sensitive adhesive layer 145 is applied to the bottom of photovoltaic module 105 either in the field by the user or at the factory and shipped to the jobsite ready to use.

FIG. 6 illustrates attaching photovoltaic module 105 using a plurality of double-sided pressure sensitive tape 150 to attach module 105 therein. Again, the adhesives may be pre-applied at the factory or may be supplied by the user during installation.

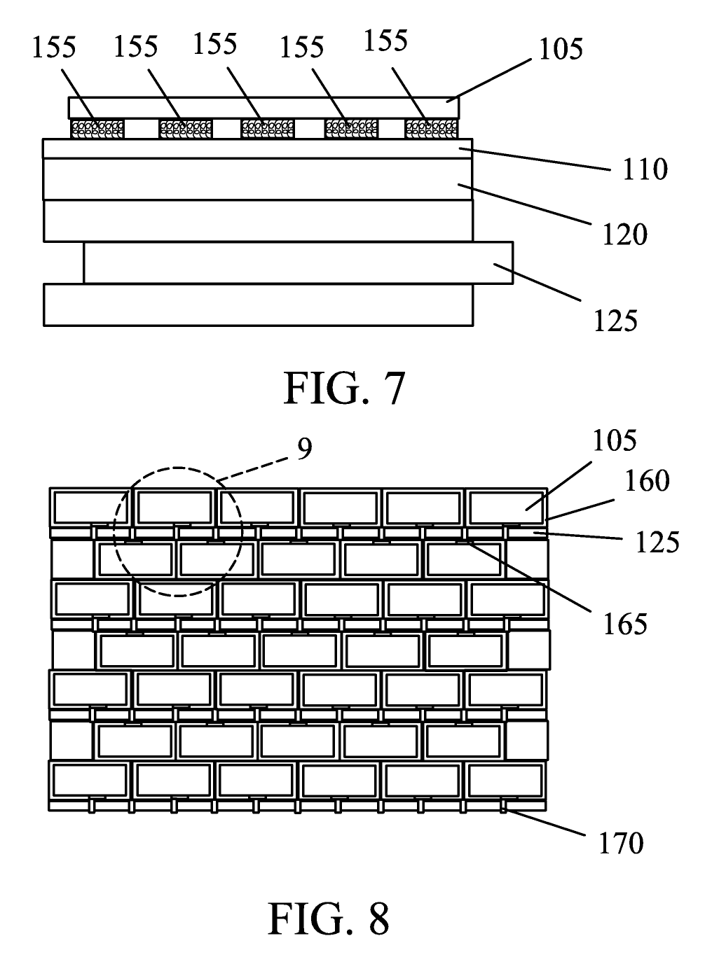

Referring now to FIG. 7, a plurality of hook and loop fasteners 155 are use to attach module 105 therein.

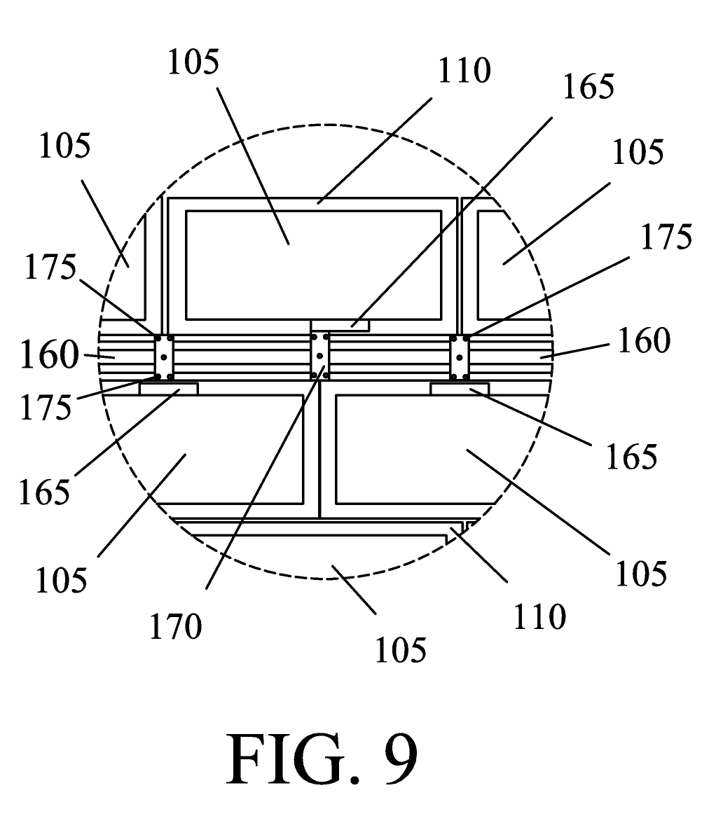

Referring now to FIGS. 8 and 9, a plurality of photovoltaic modules 105 are attached to insulative panel 125 which have been attached to a substrate such as a roof. A plurality of inter-panel power raceways 160 are either attached to the surface of insulative panel 125 or formed within them. Each module has a bus 165 and raceway connector 170 to interconnect the modules. Fasteners 175 are used to secure raceway connectors 170 but could alternatively use snaps, hook and loop fasteners or other suitable fastening scheme.

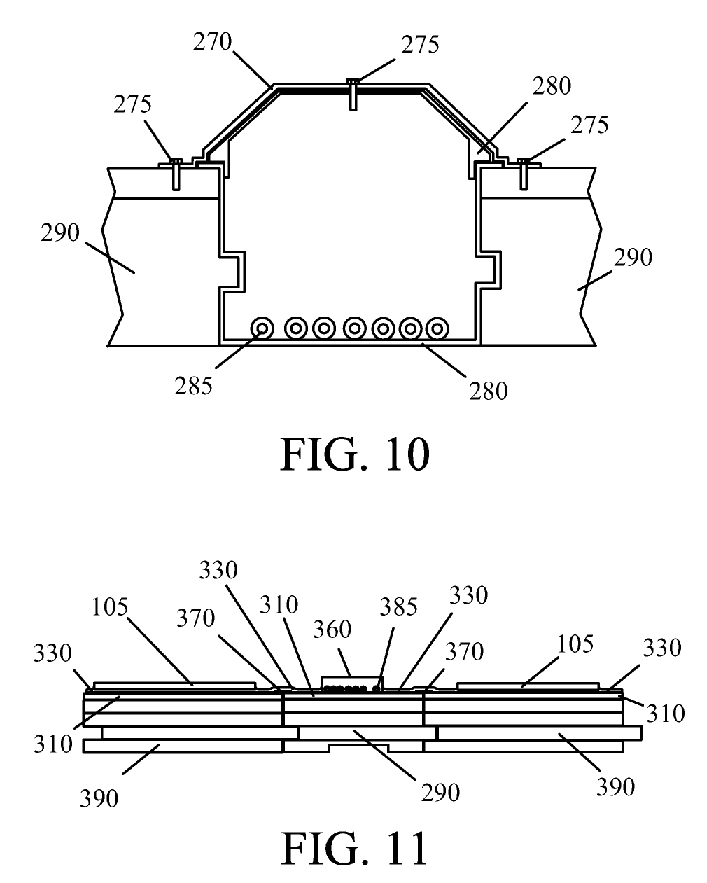

FIG. 10 illustrate an embodiment utilizing a raceway 280, a raceway connector cap 270, and fasteners 275. Power cables 285 run within raceway 280 to connect and utilize the electricity generated by photovoltaic modules 105 as is known in the art. Raceway 280 fits in the tongue and groove of insulative panels 290 to secure it therein.

FIG. 11 illustrates an embodiment with a surface mounted raceway 360 embedded in a finish elastomeric coating 330. Raceway 360 holds wires 385 as discussed above. An insulative insert 290 supports photovoltaic modules 105 and raceway 360. Raceway 360 also has tongue and groove connectors to secure it to insulative panels 390. The seams are covered with fabric 370 and then covered in finish elastomeric coating 330. In the embodiment shown, a first elastomeric coating 310 is applied, and then photovoltaic modules 105, fabric seam tape 370 and raceway 360 are embedded therein to provide a weatherproof application.

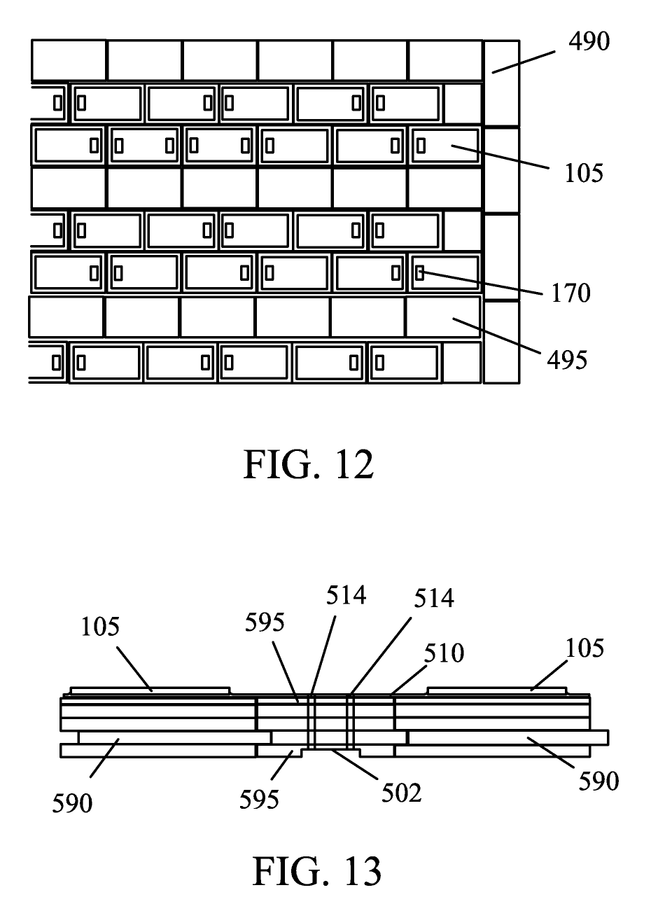

Referring to FIG. 12, an embodiment of the present invention is shown having a plurality of photovoltaic modules 105 attached to a plurality of insulative panels 490. Raceway bus and connector 170 electrically connect each module 105 to direct the electricity produced by modules 105 as is known in the art. A plurality of spacers 495 conceal the wires (not shown) within a space that is channeled out in insulative panels 490. A channel may be formed on the jobsite using a router, hot wire or knife or at the factory.

Now referring to FIG. 13, a plurality of photovoltaic modules 105 are attached to a plurality of insulative panels 590. An insulative spacer 595 is secured by the tongue and groove connectors on insulative panels 590 and has a cable channel 502 formed therein. A series of power cable holes 514 connect channel 502 to photovoltaic modules 105. In the embodiment shown, an elastomeric coating 510 is applied to weatherproof the installation.

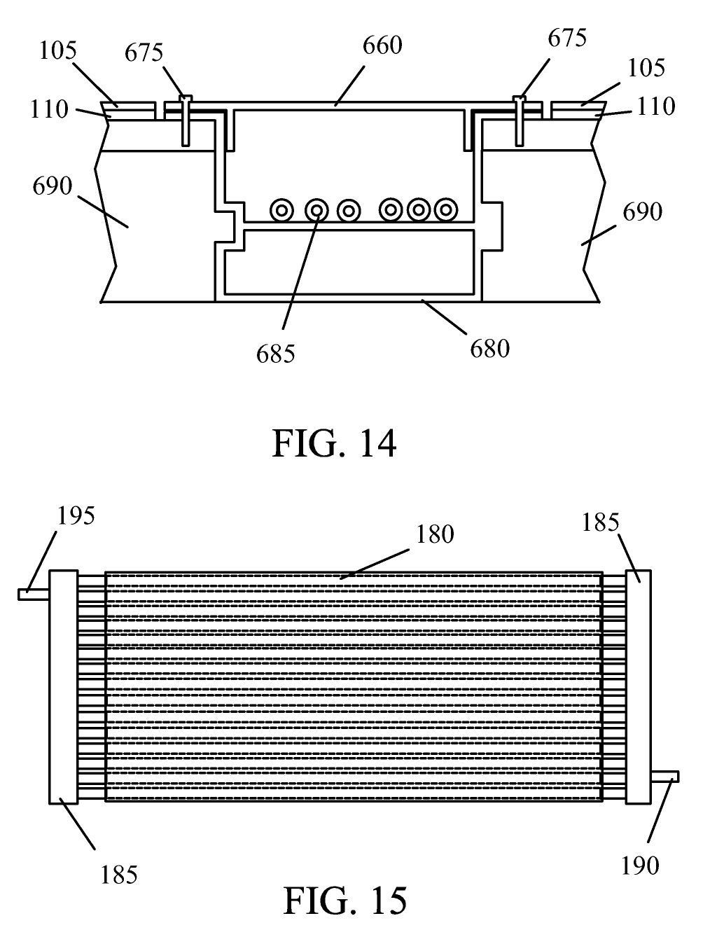

FIG. 14 is an illustration of a flush mount raceway 680 secured between insulative panels 690. A raceway cap 660 covers wires 685 and is secured with fasteners 675. Additionally a gasket or sealant (not shown) may be used to provide additional weatherproofing.

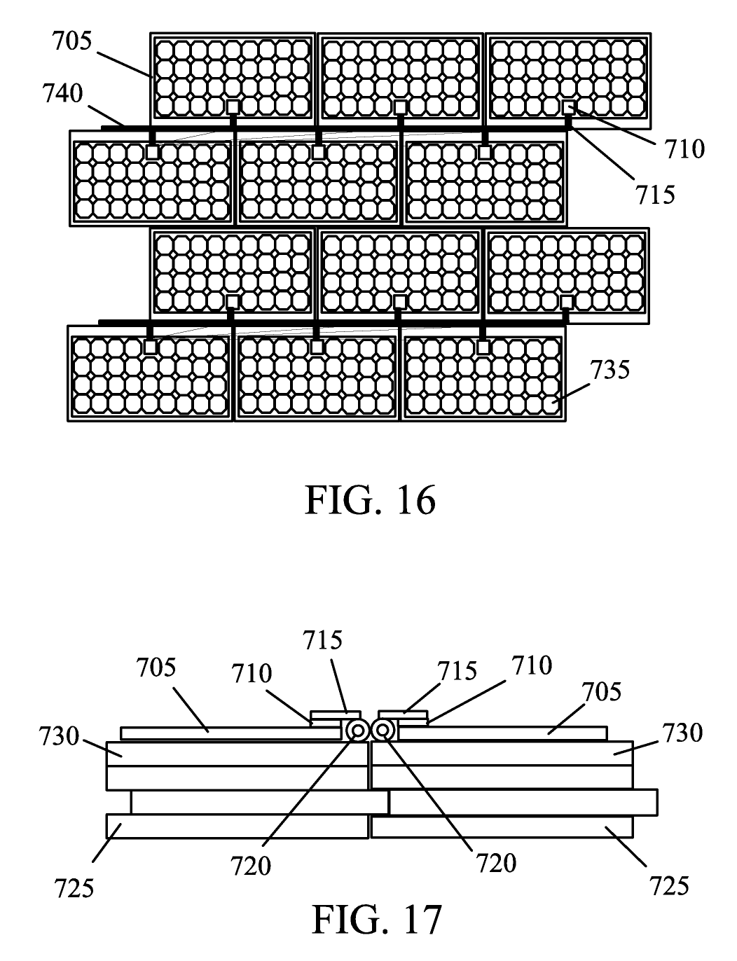

Referring now to FIGS. 16 and 17, a plurality of photovoltaic modules 705 are made up of individual photovoltaic cells 735.

Photovoltaic modules are made using non-glass technologies and include flexible, semi-flexible or rigid non-glass thin film photovoltaics or non-glass silicon modules consisting of crystalline silicon photovoltaic cells laminated to a engineered composite metal/polymer/metal panel with a solar transparent polymer top surface. Of course, other technologies are being developed and would be suitable as the photovoltaic panels are flexible. A plurality of raceways 740 cover and protect cabling 720 used to electrically connect the photovoltaic modules 705 to an inverter (not shown) and other balance of system components (not shown) as is known in the art. A plurality of junction boxes 710 and junction box wiring 715 are used to connect photovoltaic panel 705 to cabling 720.

Photovoltaic modules 705 are mounted directly to structural sheet 730 which is laminated to insulative panel 725 as discussed above. This method of directly attaching photovoltaic panel 705 to the insulative assembly enhances performance, lowers manufacturing costs and lowers the assembly costs.

Although the instant invention has been described in relation to particular embodiments thereof, many other variations and modifications and other uses will become apparent to those skilled in the art.

1. A system utilizing redeployable insulated self-ballasted photovoltaic modules, the system comprising:
at least one photovoltaic module having a first and second surface;
said first surface being adapted to receive electromagnetic radiation;
at least one insulative panel coplanar with said second surface; and
an attachment means for attaching said at least one photovoltaic module to said at least one insulative panel.

2. The system according to claim 1 wherein said at least one insulative panel has a tongue and groove connector whereby another insulative panel is fitted therein.

3. The system according to claim 1 further comprising at least one structural panel adhered to and coplanar with said insulative panel.

4. The system according to claim 3 wherein said at least one structural panel is a reinforced latex modified cementitious board.

5. The system according to claim 3 wherein said at least one structural panel is a silicone treated gypsum board.

6. The system according to claim 1 further comprising at least one elastomeric layer disposed between said at least one photovoltaic module and said at least one insulative panel.

7. The system according to claim 3 wherein said at least one structural layer is a corrugated channel panel.

8. The system according to claim 7 further comprising:
a first liquid flow cap having an intake nipple;
said first liquid flow cap being sealed against an open end of said corrugated channel panel;
a second liquid flow cap having an outlet nipple;
said second liquid flow cap being sealed against an other open end of said corrugated channel panel; and
a pump operatively connected to said intake nipple and said outlet nipple wherein a fluid is circulated therein.

9. The system of claim 1 wherein said attachment means is
an adhesive layer.

10. The system of claim 1 wherein said attachment means is
a plurality of hook and loop fasteners.

11. The system of claim 1 wherein said attachment means is
a plurality of double-sided adhesive tape.

12. The system of claim 1 wherein said attachment means is
a mechanical fastener.

13. A method for utilizing redeployable insulated self-ballasted photovoltaic modules comprising the steps of:
installing at least one insulative panel on a substrate; and
attaching at least one photovoltaic module on said at least one insulative panel.

14. The method of claim 13 wherein said at least one insulative panel has a tongue and groove connector whereby another insulative panel is fitted therein.

15. The method of claim 13 further comprising the step of applying at least one elastomeric layer over said at least one insulative panel.

16. The method of claim 15 whereby said at least one photovoltaic module is attached by embedding in said at least one elastomeric layer.

17. The method of claim 13 whereby said at least one photovoltaic module is attached using a field supplied adhesive.

18. The method of claim 13 whereby said first photovoltaic module is attached using a factory supplied adhesive.

19. The method of claim 13 whereby said first photovoltaic module is attached using a double-sided adhesive tape.

20. The method of claim 13 further comprising the steps of attaching a structural panel between said at least one insulative panel and said at least one photovoltaic module.

21. The method of claim 20 wherein said structural panel is a corrugated channel panel.

22. The method of claim 21 further comprising the steps of:
sealing a first liquid flow cap having a intake nipple to an open end of said corrugated channel panel;
sealing a second liquid flow cap having an outlet nipple to another open end of said corrugated channel panel; and
attaching a pump to said intake and outlet nipple whereby a liquid is circulated therein.
